(19) United States
(12) Patent Application Publication
(10) Pub. No.: US 2026/0336253 A1
(43) Pub. Date: Oct. 29, 2026

(54) ELASTIC MEMBER AND DISPLAY DEVICE COMPRISING SAME

(71) Applicant: LG INNOTEK CO., LTD., Seoul (KR)

(72) Inventors: Sung Won KANG, Seoul (KR); Joon Hyuk YANG, Seoul (KR); Jung Min GWAK, Seoul (KR)

(21) Appl. No.: 19/491,081

(22) PCT Filed: Jun. 10, 2024
(86) PCT No.: PCT/KR2024/007907

§ 371 Date: Dec. 8, 2025

(30) Foreign Application Priority Data
Jun. 9, 2023 (KR) 10-2023-0074190

(51) Int. Cl. B32B 3/16; B32B 3/26; B32B 7/12; B32B 15/08; H10K 59/80; H10K 102/00

(52) U.S. Cl. CPC B32B 3/16; B32B 3/266; B32B 7/12; B32B 15/08; H10K 59/873; B32B 2457/206; H10K 2102/311

(57) ABSTRACT

An elastic member according to an embodiment includes a first layer foldable based on a folding axis and having a first direction corresponding to the folding axis and a second direction perpendicular to the first direction; wherein the first layer includes a pattern part disposed in a first region adjacent to the folding axis, the pattern part including a first-first pattern and a first-second pattern that are disposed adjacent to each other in the second direction, wherein the first-first pattern includes a plurality of first inflection points in which a direction of curvature changes as a distance from a first center of the first-first pattern increases, wherein the first-second pattern includes a plurality of second inflection points in which a direction of curvature changes as a distance from a second center of the first-second pattern increases, wherein the first-first pattern and the first-second pattern include a plurality of virtual lines defined on based on the plurality of first inflection points, the plurality of second inflection points, the first center, and the second center, wherein the plurality of virtual lines include a first-first virtual line passing through two first inflection points that are spaced apart from each other in the first direction of the first-first pattern, a first-second virtual line passing through two second inflection points that are spaced apart in the first direction of the first-second pattern and are adjacent to the first-first pattern, and a second virtual line extending in the second direction and passing through the first center, wherein, on the second virtual line, the first-first virtual line and the first-first pattern are spaced apart by a first distance along the second direction, wherein, on the second virtual line, the first-second virtual line and the first-first pattern are spaced apart by a second distance along the second direction, and wherein the second distance is less than or equal to twice the first distance.

### TECHNICAL FIELD

An embodiment relates to an elastic member and a display device including the same.

### BACKGROUND ART

Recently, there is an increasing demand for a display device that is easy to carry and may display an image on a large screen.

To this end, the display device is formed in various shapes. For example, one region of the display device may be bent. Alternatively, one region of the display device may be folded.

For example, a flexible display device, a foldable display device, a sliding display device, or a rollable display device is used.

In these display devices, one region may be bent, folded, or rolled. Accordingly, a region having a curvature is formed in the display device. Accordingly, stress is generated in the region. As a result, a crack may be formed in the region. Alternatively, a crease may occur in the region.

Accordingly, reliability of the display device may be reduced.

In addition, when the elastic member is folded or rolled, a repulsive force is generated. The repulsive force acts in a direction opposite to a folding direction or a rolling direction. Accordingly, when the elastic member is manufactured, adhesion defects may occur. Accordingly, reliability of the display device may be reduced.

Therefore, a new structure of elastic member capable of solving the above problems is required.

Meanwhile, Korean Patent Publication No. KR10-2018-0079091 (Jul. 10, 2018) discloses a prior art related to an elastic member.

### DISCLOSURE

### Technical Problem

An embodiment provides an elastic member with improved folding characteristics and reliability.

### Technical Solution

An elastic member according to an embodiment comprises a first layer foldable based on a folding axis and having a first direction corresponding to the folding axis and a second direction perpendicular to the first direction; wherein the first layer includes a pattern part disposed in a first region adjacent to the folding axis, the pattern part including a first-first pattern and a first-second pattern that are disposed adjacent to each other in the second direction, wherein the first-first pattern includes a plurality of first inflection points in which a direction of curvature changes as a distance from a first center of the first-first pattern increases, wherein the first-second pattern includes a plurality of second inflection points in which a direction of curvature changes as a distance from a second center of the first-second pattern increases, wherein the first-first pattern and the first-second pattern include a plurality of virtual lines defined on based on the plurality of first inflection points, the plurality of second inflection points, the first center, and the second center, wherein the plurality of virtual lines include a first-first virtual line passing through two first inflection points that are spaced apart from each other in the first direction of the first-first pattern, a first-second virtual line passing through two second inflection points that are spaced apart in the first direction of the first-second pattern and are adjacent to the first-first pattern, and a second virtual line extending in the second direction and passing through the first center, wherein, on the second virtual line, the first-first virtual line and the first-first pattern are spaced apart by a first distance along the second direction, wherein, on the second virtual line, the first-second virtual line and the first-first pattern are spaced apart by a second distance along the second direction, and wherein the second distance is less than or equal to twice the first distance.

In addition, the two second inflection points of the first-second pattern are disposed in a region between the first-first virtual line and the first-first pattern.

In addition, the two second inflection points of the first-second pattern are disposed between the first-first virtual line and the first center of the first-first pattern in the second direction.

In addition, a partial region of the first-second pattern is disposed in a region between the first-first virtual line and the first-first pattern.

In addition, the partial region of the first-second pattern overlaps the first-first pattern along the first direction.

In addition, the first distance is greater than the second distance.

In addition, the first distance is smaller than the second distance.

In addition, the first-first pattern and the first-second pattern are spaced apart by a third distance along the second direction, and the third distance is greater than the first distance.

In addition, at least one of the two inflection points of the first-second pattern is in contact with the first-first virtual line.

In addition, the first layer includes a plurality of hinge parts penetrating an end in the first direction.

In addition, the plurality of hinge parts include a region whose width in the second direction changes along the first direction.

In addition, the width of the hinge part in the second direction increases as a distance from the end increases.

In addition, the width of the hinge part in the second direction is smallest at the end.

In addition, the first-first pattern has a first width corresponding to a distance between two first inflection points facing in the second direction, and a second width smaller than the first width on the second virtual line.

In addition, the first-second pattern has a third width corresponding to a distance between two second inflection points facing in the second direction, and a fourth width smaller than the third width on a third virtual line passing through the second center in the second direction.

In addition, each of the first-first pattern and the first-second pattern includes a plurality of patterns spaced apart in the first direction,

A first spacing in the first direction between a plurality of adjacent first-first patterns is greater than a second spacing in the first direction between a plurality of adjacent first-second patterns.

The first region includes a first-first region and a first-second region that that is located farther from the folding axis than the first-first region.

### Advantageous Effects

An elastic member according to an embodiment includes a first layer, a second layer, and a third layer.

The first layer includes a first region and a second region. A pattern part is disposed in at least one of the first region and the second region.

The pattern part may include a first-first pattern and a first-second pattern that are adjacent to each other. In addition, a first-first virtual line, a first-second virtual line, and a second virtual line are defined by the pattern part.

The first-first virtual line passes through an inflection point of the first-first pattern. In addition, the first-second virtual line passes through an inflection point of the first-second pattern. In addition, the second virtual line passes through a center of the first-first pattern.

The inflection point of the first-second pattern may be disposed in a region between the first-first virtual line and the first-first pattern. Alternatively, the inflection point of the second pattern may not be disposed in a region between the first-first virtual line and the first-first pattern. Alternatively, the inflection point of the first-second pattern may contact the first-first virtual line. That is, the first-first virtual line and the first-second virtual line may overlap.

Therefore, when folding the elastic member, stress applied to the first layer is reduced. In addition, when folding the elastic member, a repulsive force of the first layer is reduced. In addition, when folding the elastic member, the distortion of a residual region between adjacent patterns is reduced.

Therefore, the elastic member according to the embodiment has improved folding characteristics and reliability.

### DESCRIPTION OF DRAWINGS

FIG. 1 is a perspective view of a display device according to an embodiment.

FIG. 2 is a perspective view of an elastic member according to a first embodiment.

FIG. 3 is a side view of an elastic member according to a first embodiment, before folding.

FIG. 4 is a side view of an elastic member according to a first embodiment, after folding.

FIG. 5 is a cross-sectional view of a layer structure of an elastic member according to an embodiment.

FIG. 6 is a top view of a first layer of an elastic member according to a first embodiment.

FIG. 7 is an enlarged view of a pattern of an elastic member according to a first embodiment.

FIG. 8 is an enlarged view of the A region of FIG. 6.

FIGS. 9 and 10 are enlarged views of the B region of FIG. 8.

FIG. 11 is another enlarged view of the A region of FIG. 6.

FIGS. 12 and 13 are enlarged views of the C region of FIG. 11.

FIG. 14 is another enlarged view of the A region of FIG. 6.

FIG. 15 is an enlarged view of the D region of FIG. 14.

FIG. 16 is an enlarged view of the E region of FIG. 6.

FIG. 17 is another top view of a first layer of an elastic member according to a first embodiment.

FIGS. 18 (a) and (b) are diagrams illustrating the reaction force according to the embodiment and comparative example.

FIG. 19 is a top view of the first layer of the elastic member according to a second embodiment.

FIG. 20 is a side view of the first sliding mode of the first layer of the elastic member according to the second embodiment.

FIG. 21 is a side view of the second sliding mode of the first layer of the elastic member according to the second embodiment.

FIG. 22 is a top view of the first layer of the elastic member according to the third embodiment.

FIG. 23 is a side view of the first rollerball mode of the first layer of the elastic member according to the third embodiment.

FIG. 24 is a side view of the second rollerball mode of the first layer of the elastic member according to the third embodiment.

FIG. 25 is a cross-sectional view of a folding support including an elastic member according to an embodiment.

FIG. 26 is a cross-sectional view of a display device including a folding support according to an embodiment.

FIG. 27 is a diagram illustrating an application example of a display device according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, an elastic member, a folding support and a display device including the same according to an embodiment will be described with reference to drawings.

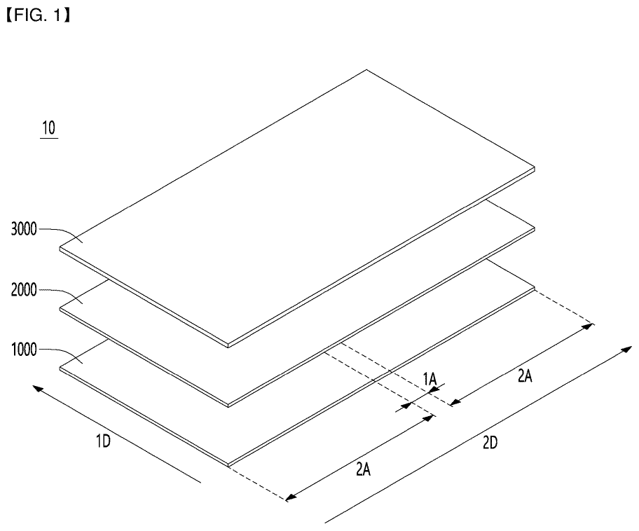

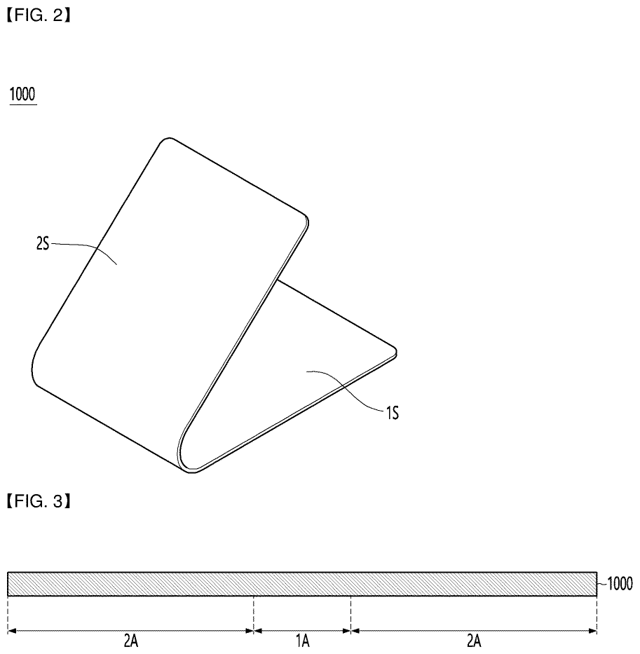

FIG. 1 is a perspective view of a display device. FIGS. 2 to 4 are perspective views and cross-sectional views of an elastic member.

Referring to FIG. 1, a display device 10 includes an elastic member 1000 and a panel. The panel may include at least one of a display panel 2000 and a touch panel 3000.

The elastic member 1000, the display panel 2000, and the touch panel 3000 may be bonded to each other by an adhesive layer.

The elastic member 1000 supports the display panel 2000 and the touch panel 3000. The elastic member 1000 may be a supporting substrate supporting the display panel 2000 and the touch panel 3000.

The elastic member 1000 includes at least one of a metallic material and a non-metallic material. For example, the elastic member 1000 may include a plurality of layers. The plurality of layers may include at least one of the metallic and non-metallic materials.

For example, the elastic member 1000 may include at least one of a metal, a metal alloy, a plastic, a composite material (e.g., carbon fiber reinforced plastic, a magnetic or conductive material, or a glass fiber reinforced material), a ceramic, a sapphire, and a glass.

The elastic member 1000 has elasticity. Accordingly, the elastic member 1000 can be bent in one direction. For example, the elastic member 1000 can be folded in one direction. That is, the elastic member 1000 may be a display substrate applied to a foldable display device.

The elastic member 1000 is defined in a first direction 1D and a second direction 2D. For example, the first direction 1D is defined as a same direction as a folding axis of the elastic member 1000. The second direction 2D is defined as a direction perpendicular to the first direction 1D.

Hereinafter, the first direction 1D is defined as the same direction as the folding axis. Furthermore, the first direction 1D is defined as a width direction of the elastic member 1000. Furthermore, the second direction 2D is defined as a longitudinal direction of the elastic member 1000.

The elastic member 1000 may include at least two regions. For example, the elastic member 1000 may include a first region 1A and a second region 2A.

The first region 1A is defined as a region where the elastic member 1000 folds. In other words, the first region 1A is a folding region.

Furthermore, the second region 2A is defined as a region where the elastic member 1000 does not fold. That is, the second region 2A is an unfolding region.

The display panel 2000 is disposed on the elastic member 1000.

The display panel 2000 may include a plurality of pixels. Each pixel may include a switching thin-film transistor, a driving thin-film transistor, a capacitor, and an organic light emitting diode (OLED). The organic light emitting diode can be deposited at a relatively low temperature. Therefore, it has low power consumption and high brightness, making it suitable for use in display devices. Here, a pixel refers to a minimum unit for displaying an image. The display panel displays an image through a plurality of pixels.

The display panel 2000 may include a substrate, a gate line disposed on the substrate, a data line intersecting the gate line in an insulated manner, and a common power line. Typically, one pixel may be defined by the boundary between the gate line, the data line, and the common power line.

The substrate may include a flexible material, such as a plastic film. The display panel 2000 may be formed by arranging organic light-emitting diodes and pixel circuits on a flexible film.

The touch panel 3000 is disposed on the display panel 2000. The display device has a touch function by the touch panel 3000. Alternatively, a display device that only displays images without the touch function may omit the touch panel.

The touch panel 3000 includes a substrate and touch electrodes disposed on the substrate. The touch electrodes can detect a position of an input device touching the display device using a capacitive or resistive method.

The substrate of the touch panel 3000 may include a material having flexible properties, such as a plastic film. The touch panel 3000 may be implemented by arranging touch electrodes on the flexible film.

The touch panel 3000 may be formed integrally with the display panel 2000. For example, the touch panel 3000 may be formed integrally with the display panel 2000 in an on-cell or in-cell manner. Accordingly, the substrate of the touch panel 3000 may be a substrate of the display panel or a portion of the display panel. Accordingly, the touch panel 3000 and the display panel 2000 may be formed integrally. Therefore, a thickness of the display device may be reduced.

The elastic member 1000 and the display panel 2000 may have different sizes.

For example, the area of the elastic member 1000 may be 90% or more and 110% or less of the area of the display panel 2000. In detail, the area of the elastic member 1000 may be 95% or more and 105% or less of the area of the display panel 2000. More specifically, the area of the elastic member 1000 may be 97% or more and 100% or less of the area of the display panel 2000.

If the area of the elastic member 1000 is less than 90% of the area of the display panel 2000, the supporting force of the elastic member 1000 supporting the display panel 2000 and the touch panel 3000 is reduced. Accordingly, curling may occur in the unfolding region of the elastic member 1000.

In addition, if the area of the elastic member 1000 exceeds 110% of the area of the display panel 2000, a bezel region of the foldable display device may increase.

Meanwhile, although not shown in the drawing, a cover window may be additionally disposed above the touch panel 3000 or above the display panel 2000 (if the touch panel is omitted). The cover window may protect the display device.

Referring to FIG. 2, the elastic member 1000 may be bent in one direction.

Specifically, the elastic member 1000 includes a first surface 1S and a second surface 2S. The first surface 1S and the second surface 2S are opposite to each other. The elastic member 1000 can be bent so that the first surface 1S or the second surface 2S face each other. Accordingly, the elastic member 1000 can be bent so that a surface on which the panel is disposed faces each other. Alternatively, the elastic member 1000 can be bent so that a surface opposite the surface on which the panels is disposed face each other.

Hereinafter, the elastic member will be described as being bent in a direction in which the first surface 1S faces each other.

As previously described, the elastic member 1000 includes a first region 1A and a second region 2A. The first region 1A and the second region 2A are regions defined when the elastic member 1000 is bent.

In detail, when the elastic member 1000 is bent in one direction, the elastic member 1000 can be divided into a first region 1A, which is a folding region, and a second region 2A, which is an unfolding region.

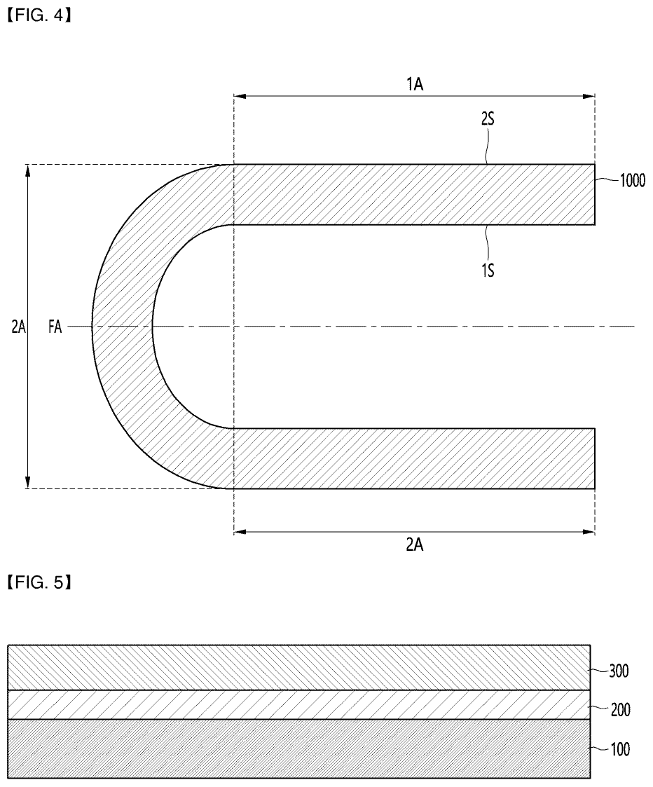

Referring to FIGS. 3 and 4, the elastic member 1000 includes a first region 1A that is bendable. Furthermore, the elastic member 1000 includes a second region 2A that is not bendable.

The second region 2A may be formed at left and right sides of the first region 1A, respectively. That is, the second region 2A may be disposed at both ends of the first region 1A. That is, the first region 1A may be disposed between second regions 2A.

However, the embodiment is not limited thereto. For example, the first region 1A may be further formed outside the second region 2A.

Sizes of the first region 1A and the second region 2A may differ. For example, an area of the second region 2A may be larger than an area of the first region 1A.

For example, the area of the first region 1A may be 1% to 30% of a total area of the elastic member 1000. Specifically, the area of the first region 1A may be 5% to 20% of the total area of the elastic member 1000. More specifically, the area of the first region 1A may be 10% to 15% of the total area of the elastic member 1000.

If the area of the first region 1A is less than 1% of the total area of the elastic member 1000, cracks may occur at an interface between the folding region and the unfolding region of the elastic member. Consequently, the folding reliability of the elastic member 1000 may be reduced.

In addition, if the area of the first region 1A exceeds 30% of the total area of the elastic member 1000, curling may occur in the first region 1A when folding the elastic member.

In FIGS. 3 and 4, the first region 1A is illustrated as being located at a center of the elastic member 1000. However, the embodiment is not limited thereto. For example, the first region 1A may be located at one end and an end region of the elastic member 1000.

Referring to FIG. 4, the elastic member 1000 bends in one direction around the folding axis. Specifically, the elastic member 1000 folds along the folding axis in a direction in which the first surface 1S faces each other.

The first region 1A may be defined as a region in which a curvature (R) is formed. In addition, the second region 2A may be defined as a region in which a curvature (R) is not formed. Alternatively, the second region 2A may be defined as a region in which the curvature is close to 0.

A plurality of pattern parts may be formed in at least one of the first region 1A and the second region 2A. The stress generated when folding the elastic member 1000 may be reduced by the pattern parts. The pattern parts will be described below.

The elastic member 1000 includes a plurality of layers. Referring to FIG. 5, the elastic member 1000 includes a first layer 100, a second layer 200, and a third layer 300. The first layer 100, the second layer 200, and the third layer 300 are sequentially disposed. The first layer 100, the second layer 200, and the third layer 300 each include the first region 1A and the second region 2A.

The first layer 100 may include a metal. For example, the first layer 100 may include a metal or a metal alloy. For example, the first layer 100 may include at least one of stainless steel (SUS) and copper (Cu). Alternatively, the first layer 100 may include a copper alloy including at least one of nickel (Ni), chromium (Cr), iron (Fe), titanium (Ti), manganese (Mn), molybdenum (Mo), silver (Ag), zinc (Zn), nitrogen (N), and aluminum (Al).

The first layer 100 may have a set thickness. The thickness of the first layer 100 may be 30 μm, 50 μm, 100 μm, or 150 μm or more. For example, the thickness of the first layer 100 may be 30 μm to 200 μm.

Alternatively, the first layer 100 may include a non-metal. For example, the first layer 100 may include a base material and fibers. Specifically, the first layer 100 may include the base material and fibers disposed within the base material.

The base material accommodates the fibers. The base material supports the fibers.

The base material may include a resin material. For example, the base material may include at least one resin material selected from the group consisting of polyimide, polysulfone, polyphenylene sulfide, polyamide-imide, polyether ether ketone, liquid-crystal polyester, polyamide, polyoxymethylene, polycarbonate, polybutylene terephthalate, modified polyphenylene oxide, epoxy, and acrylate.

The fiber is disposed within the base material. For example, the fiber may be impregnated within the base material.

The fiber may include an elastic material. For example, the fiber may include at least one of carbon fiber, glass fiber, and ceramic fiber. Preferably, the fiber includes carbon fiber.

The fiber may have a predetermined length and diameter. For example, the fiber may have a diameter of 0.0001 mm to 0.01 mm. Additionally, the length of the fiber may vary depending on a size of the base material.

The first layer 100 includes a plurality of pattern parts. The pattern parts will be described in detail below.

The second layer 200 is disposed on the first layer 100.

The second layer 200 may include an adhesive. The second layer 200 may be an adhesive layer. The first layer 100 and the third layer 300 are bonded by the second layer 200.

For example, the second layer 200 may include a pressure-sensitive adhesive (PSA).

The third layer 300 may be a planarizing layer. The third layer 300 may planarize the surface of the first layer 100.

The third layer 300 may include a metal or a non-metal. For example, the third layer 300 may include a non-metal. For example, the third layer 300 may include plastic.

However, the embodiment is not limited thereto. The elastic member may not include the second layer 200. Specifically, the elastic member may include the first layer 100 and a third layer 300 on the first layer 100.

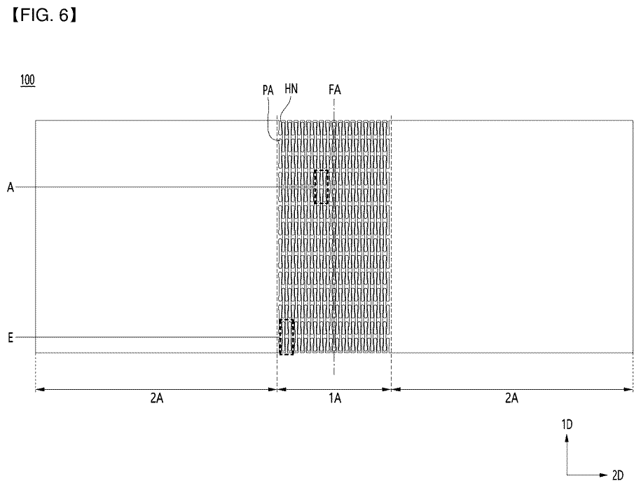

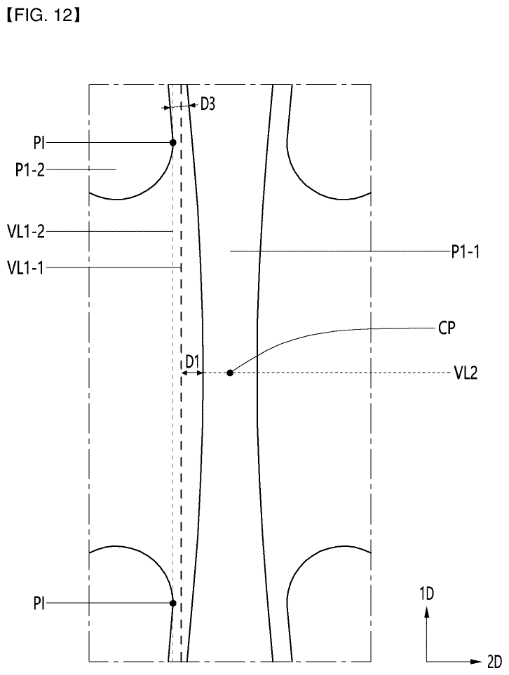

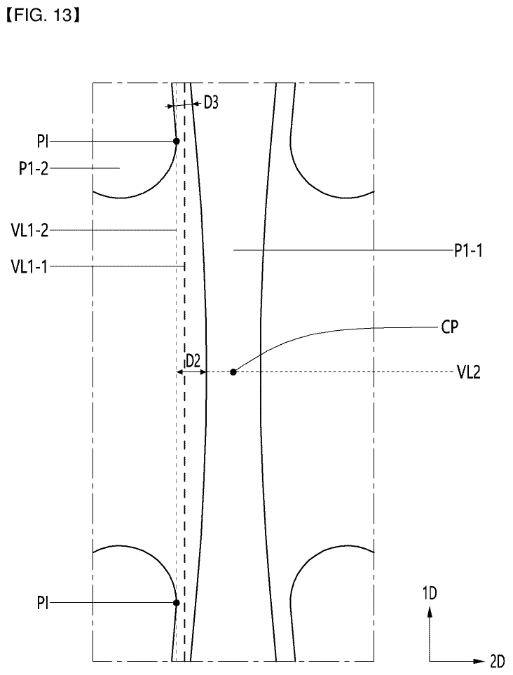

Hereinafter, an elastic member according to a first embodiment will be described with reference to FIGS. 6 to 16.

Referring to FIG. 6, the first layer 100 includes a plurality of pattern parts.

Specifically, the pattern part PA is disposed in the first region 1A.

The pattern part PA is formed by penetrating the first layer 100. For example, the pattern part PA may be formed in a hole shape penetrating the first layer 100. Alternatively, the pattern part PA may be formed in a groove shape partially penetrating the first layer 100.

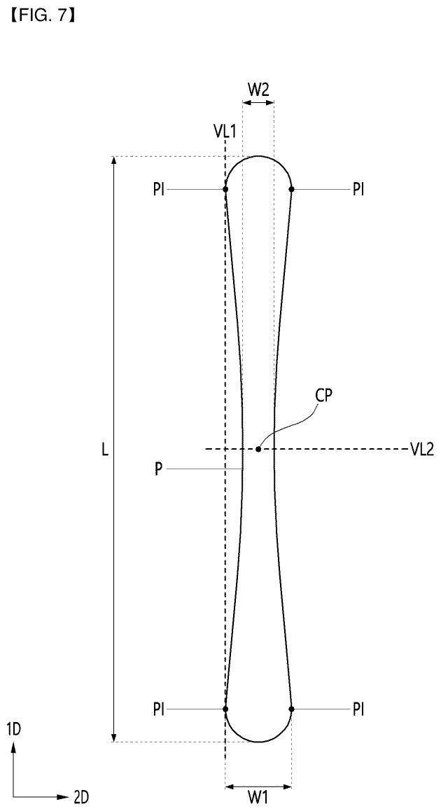

Referring to FIG. 7, a center CP is defined in the pattern P of the pattern part PA. In addition, the pattern P includes a plurality of inflection points PI. The inflection points PI are regions where a direction of curvature of the pattern changes from the center CP toward an end of the first direction 1D. A first virtual line VL1 and a second virtual line VL2 may be defined by the pattern P.

The first virtual line VL1 passes through two inflection points PI of the pattern P. The first virtual line VL1 passes through the inflection points PI of the pattern P that face each other in the first direction 1D. A width of the pattern P in the second direction may be greatest in a region between the inflection points PI that face each other in the second direction.

The first virtual line VL1 may be parallel to the first direction 1D. The second virtual line VL2 passes through the center of the pattern P. The second virtual line VL2 may be parallel to the second direction 2D.

The width of the pattern P varies. In detail, the width of the pattern P changes as it extends from the inflection point PI through which the first virtual line VL1 passes toward the center CP. In detail, the width of the pattern P decreases as it extends from the inflection point PI toward the center CP. The center CP may be a center of a region of the pattern P having a narrowest width in the second direction 2D. The center CP may be a point where a center line of the pattern P in the first direction intersects the center line of the pattern P in the second direction. The center CP may be a point where a long width and a short width of the pattern P intersect.

Accordingly, the pattern P may have a first width W1 and a second width W2. The first width W1 may be defined as the long width of the pattern P. The first width W1 may be defined as a distance between inflection points PI facing each other in the second direction 2D. The second width W2 may be defined as the short width of the pattern P. The second width W2 may be defined as a width passing through the center CP in the second direction 2D.

The first width W1 may be at least 1.2 times the second width W2. Specifically, the first width W2 may be 1.2 to 5 times, 1.5 to 4 times, or 1.7 to 3 times the second width W2.

If the first width W1 is less than 1.2 times the second width W2, a difference between the first width W1 and the second width W2 is reduced. As a result, the effect of reducing stress by the pattern part PA is reduced. If the first width W1 is more than twice the second width W2, a size of the first width W1 increases. As a result, the number of patterns P disposed in the first layer 100 decreases. In addition, a spacing between adjacent patterns may narrow. As a result, adjacent patterns may overlap during a process.

The second width W2 may be 20% or less of a length L of the pattern P. Specifically, the second width W2 may be 1% to 20%, 2% to 15%, or 4% to 10% of the length L.

If the second width W2 is less than 1% of the length L, the second width W2 becomes very small. As a result, a central region of the pattern may not be removed and may remain during the process. If the second width W2 exceeds 20% of the length L, a size of the second width W2 increases. As a result, the first width W1 also increases. Consequently, the number of patterns P disposed in the first layer 100 decreases. Furthermore, the spacing between adjacent patterns may narrow. As a result, adjacent patterns may overlap during the process.

For example, the second width W2 may be 0.1 mm or greater. Specifically, the second width W2 may be 0.1 mm to 0.2 mm, 0.12 mm to 0.18 mm, or 0.14 mm to 0.16 mm.

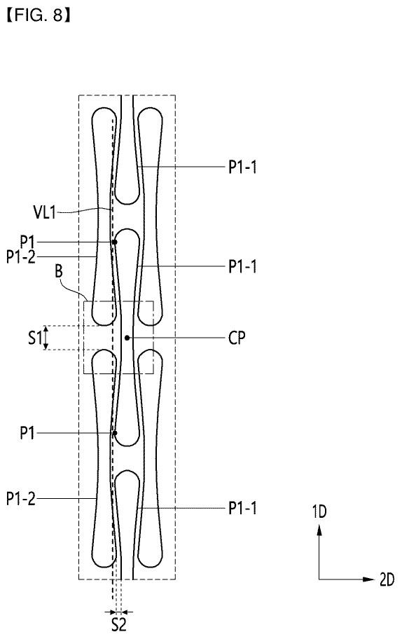

Referring to FIG. 8, the patterns are spaced apart in the first direction 1D and the second direction 2D. Accordingly, the pattern part P has a first spacing S1 in the first direction 1D and a second spacing S2 in the second direction 2D.

The patterns may include a first-first pattern P1-1 and a first-second pattern P1-2. The first-first pattern P1-1 and the first-second pattern P1-2 are spaced apart in the second direction 2D.

The first-first pattern P1-1 includes a plurality of first-first patterns P1-1 spaced apart in the first direction 1D.

The first-second pattern P1-2 includes a plurality of first-second patterns P1-2 spaced apart in the first direction 1D.

The first spacing S1 is a distance in the first direction 1D between adjacent first-first patterns P1-1. Furthermore, the first spacing S1 is a distance in the first direction 1D between adjacent first-second patterns P1-2.

The first spacing S1 in the first direction between adjacent first-first patterns P1-1 may be different from the first spacing S1 in the first direction between first-second patterns P1-2 spaced apart from the first-first pattern P1-1 in the second direction.

The sizes of the first-first patterns P1-1 and the first-second patterns P1-2 may be different.

The first spacing S1 may decrease as a distance from the folding axis increases.

The size of the first pattern may decrease as a distance from the folding axis increases.

Accordingly, the shape and spacing of the pattern can be adjusted as the stress varies with distance from the folding axis. Therefore, the entire stress of the elastic member can be adjusted.

In addition, the second spacing S2 is a distance in the second direction 2D between the adjacent first-first pattern P1-1 and the first-second pattern P1-2.

The second spacing S2 is a spacing between the first-first pattern P1-1 and the first-second pattern P1-2 adjacent in the second direction. The second spacing S2 may vary depending on the position in the first direction. That is, a second spacing S2 spaced apart in the second direction from the inflection point P1 may be different from a second spacing S2 spaced apart in the second direction in a region between the inflection point P1 and the center CP.

Therefore, the stress distribution of the elastic member can be distributed. Therefore, the stress generated when the elastic member bends can be minimized.

The first spacing S1 and the second spacing S2 are different. Specifically, the first spacing S1 is greater than the second spacing S2. That is, the first spacing S1 in a direction parallel to the folding axis FA is greater than the second spacing S2. That is, the first spacing S1 in a direction perpendicular to the folding direction is greater than the second spacing S2.

The first layer 100 folds in the second direction 2D. Accordingly, the stress moves in the second direction 2D. Since the first spacing S1 is formed to be greater than the second spacing S2, the stress can be easily distributed by the first spacing S1.

In addition, since the second spacing S2 is formed small, a region (residual region RA in FIG. 18) between the first-first pattern P1-1 and the first-second pattern P1-2 torsions differently at each position in the first direction. Accordingly, since stress acts differently at each position in the first direction in the region, the overall stress of the region can be distributed.

For example, the first spacing S1 may be at least three times the second spacing S2. Specifically, the first spacing S1 may be 3 to 7 times, 3.5 to 6 times, or 4 to 5 times the second spacing S2.

For example, the first spacing S1 may be at least 0.2 mm. In detail, the first spacing S1 may be 0.2 mm to 0.5 mm, 0.25 mm to 0.45 mm, or 0.27 mm to 0.4 mm. In addition, the second spacing S2 may be 0.1 mm or less. In detail, the second spacing S2 may be 0.03 mm to 0.1 mm, 0.04 mm to 0.9 mm, or 0.05 mm to 0.8 mm.

For example, the second spacing S2 may be 1% or less of a thickness of the first layer 100. The second spacing S2 may be 0.01% to 1% of the thickness of the first layer 100. In detail, the second spacing S2 may be 0.015% to 0.8%, 0.02% to 0.6%, or 0.03% to 0.5% of the thickness of the first layer 100.

Accordingly, a region (residual region RA in FIG. 18) between the first-first pattern P1-1 and the first-second pattern P1-2 torsions differently at each position in the first direction.

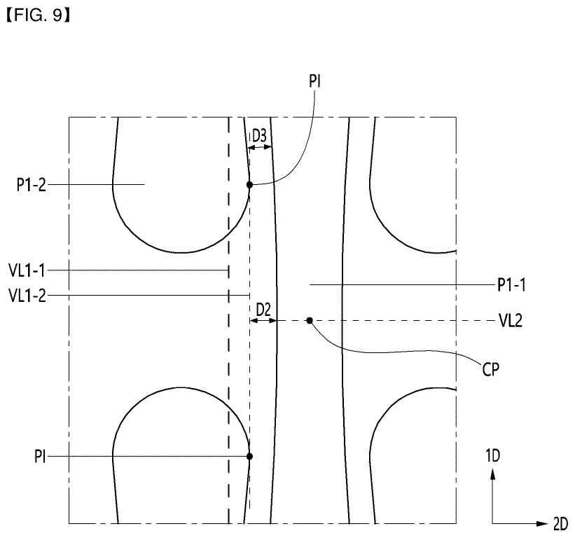

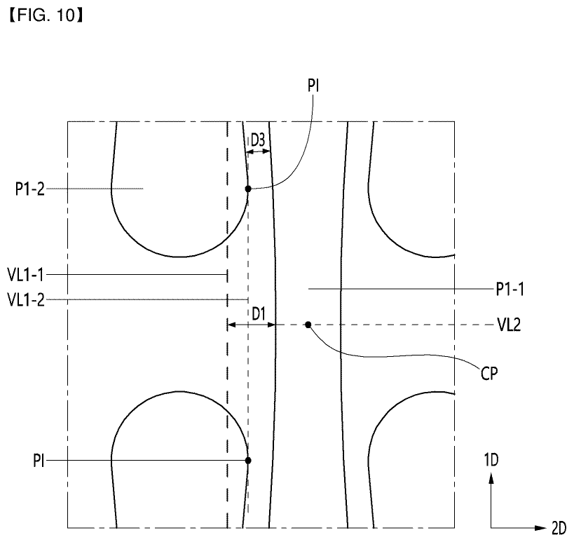

Referring to FIGS. 9 and 10, the first virtual line VL1 includes a first-first virtual line VL1-1 and a first-second virtual line VL1-2.

The first-first virtual line VL1-1 passes through the inflection point of the first-first pattern P1-1. The first-first virtual line VL1-1 extends in the first direction 1D. The first-second virtual line VL1-2 passes through the inflection point of the first-second pattern P1-2. The first-second virtual line VL1-2 extends in the first direction 1D.

A distance between the first-first virtual line VL1-1 and the first-first pattern part P1-1 on the second virtual line VL2 passing through the center CP of the first-first pattern part P1-1 is defined as a first distance D1.

A distance between the first-second virtual line VL1-2 and the first-first pattern part P1-1 on the second virtual line VL2 passing through the center CP of the first-first pattern part P1-1 is defined as a second distance D2.

The inflection point PI of the first-second pattern part P1-2 is disposed in a region between the first-first virtual line VL1-1 and the first-first pattern P1-1. Accordingly, a partial region of the first-second pattern P1-2 is disposed in a region between the first-first virtual line VL1-1 and the first-first pattern P1-1.

The first-first pattern part P1-1 and the first-second pattern part P1-2 are spaced apart by a third distance D3.

The third distance D3 is defined as a distance in a region where a side surface of the first-first pattern part P1-1 and a side surface of the first-second pattern part P1-2 are closest to each other.

The first distance D1, the second distance D2, and the third distance D3 may be different. For example, the second distance D2 is smaller than the first distance D1.

Furthermore, the second distance D2 and the third distance D3 may be the same or different. For example, the second distance D2 and the third distance D3 may be the same. Alternatively, the second distance D2 may be greater than the third distance D3. Alternatively, the third distance D3 may be greater than the second distance D2.

For example, the third distance D3 may be 0.05 mm or greater. Specifically, the third distance D3 may be 0.05 mm to 0.8 mm, 0.055 mm to 0.75 mm, or 0.6 mm to 0.7 mm.

Since the second spacing D2 is formed smaller than the first spacing D1, the torsion of the region (residual region, RA) between the first-first pattern P1-1 and the first-second pattern P1-2 can vary depending on the location. Therefore, since the stress in the region varies depending on the location, the overall stress can be distributed.

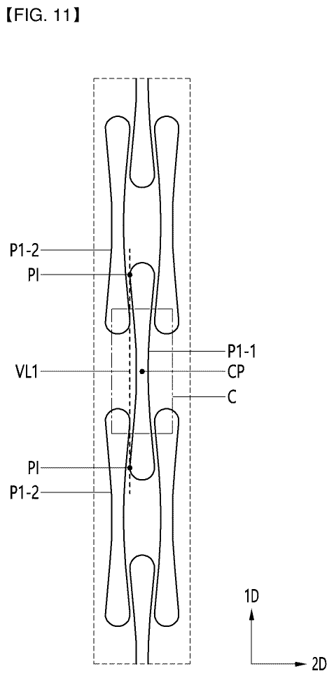

In another embodiment, referring to FIGS. 11 to 13, the first virtual line VL1 includes a first-first virtual line VL1-1 and a first-second virtual line VL1-2.

The first-first virtual line VL1-1 passes through the inflection point of the first-first pattern P1-1. The first-first virtual line VL1-1 extends in the first direction 1D. The first-second virtual line VL1-2 passes through the inflection point of the first-second pattern P1-2. The first-second virtual line VL1-2 extends in the first direction 1D.

A distance between the first-first virtual line VL1-1 and the first-first pattern part P1-1 at the second virtual line VL2 passing through the center CP of the first-first pattern part P1-1 is defined as a first distance D1.

A distance between the first-second virtual line VL1-2 and the first-first pattern part P1-1 at the second virtual line VL2 passing through the center CP of the first-first pattern part P1-1 is defined as a second distance D2.

The inflection point PI of the first-second pattern part P1-2 may not be disposed in a region between the first-first virtual line VL1 and the first-first pattern P1-1. Accordingly, the first-second pattern P1-2 may not be disposed in a region between the first-first virtual line VL1 and the first-first pattern P1-1.

At this time, the second distance D2 may be less than or equal to twice the first distance D1. In detail, the second distance D2 may be less than or equal to 1.8 times, less than or equal to 1.6 times, less than or equal to 1.4 times, or less than or equal to 1.2 times the first distance D1.

If the second spacing D2 exceeds twice the first spacing D1, the second spacing S2 becomes too wide. Accordingly, a region between the first-first pattern P1-1 and the first-second pattern P1-2 is not twisted differently at each location, but rather twisted as a whole. Accordingly, similar to FIG. 18(b), the maximum stress is greater than that of FIG. 18 (a), preventing smooth stress distribution.

That is, if the second spacing D2 is less than twice the first spacing D1, the torsion of the region (residual region, RA) between the first-first pattern P1-1 and the first-second pattern P1-2 may vary at each location. Therefore, since the stress in the region varies at each location, the overall stress can be distributed.

The first-first pattern part P1-1 and the first-second pattern part P1-2 are separated by a third distance D3.

The third distance D3 defined as a distance in a region where a side surface of the first-first pattern part P1-1 and a side surface of the first-second pattern part P1-2 are closest to each other.

The first distance D1, the second distance D2, and the third distance D3 may be different. For example, the second distance D2 may be greater than the first distance D1.

In addition, the third distance D3 may be greater than the first distance D1. The third distance D3 is less than twice the first distance D1.

For example, the third distance D3 may be 0.05 mm or greater. Specifically, the third distance D3 may be 0.05 mm to 0.8 mm, 0.055 mm to 0.75 mm, or 0.6 mm to 0.7 mm.

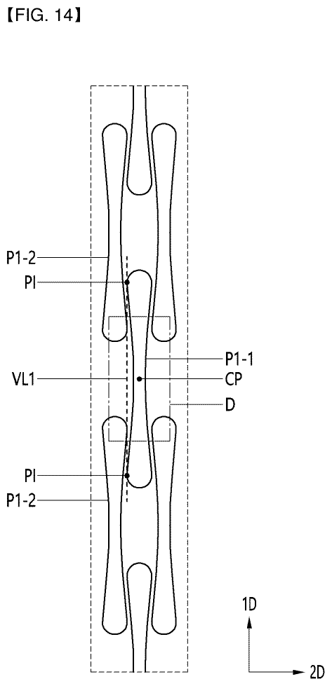

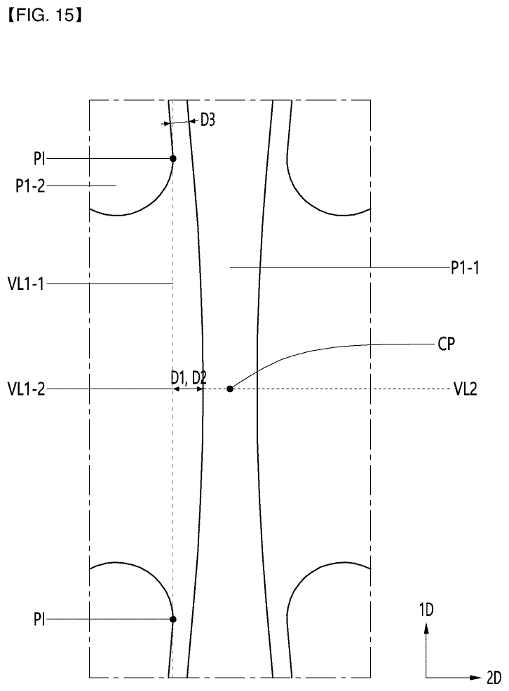

In another embodiment, referring to FIGS. 14 and 15, the first virtual line VL1 includes a first virtual line VL1-1 and a second virtual line VL1-2.

The first virtual line VL1-1 passes through the inflection point of the first pattern P1-1. The first virtual line VL1-1 extends in the first direction 1D. The first-second virtual line VL1-2 passes through the inflection point of the first-second pattern P1-2. The first-second virtual line VL1-2 extends in the first direction 1D.

The first-first virtual line VL1-1 and the first-second virtual line VL1-2 overlap. Specifically, the first-first virtual line VL1-1 and the first-second virtual line VL1-2 overlap in the first direction 1D.

A distance between the first-first virtual line VL1-1 and the first-first pattern part P1-1 at the second virtual line VL2 passing through the center CP of the first-first pattern part P1-1 is defined as a first distance D1.

A distance between the first-second virtual line VL1-2 and the first-first pattern part P1-1 at the second virtual line VL2 passing through the center CP of the first-first pattern part P1-1 is defined as a second distance D2.

The first distance D1 is defined as a maximum distance between the first-first virtual line VL1-1 and the first-first pattern part P1-1. Furthermore, the second distance D2 is defined as a maximum distance between the first-second virtual line VL1-2 and the first-first pattern part P1-1.

The first-first virtual line VL1-1 and the first-second pattern part P1-2 are in contact. Furthermore, the first-second virtual line VL1-2 and the first-second pattern part P1-2 are in contact. Specifically, the first-first virtual line VL1-1 and the first-second virtual line VL1-2 are in contact with the inflection points PI of the first-first pattern part P1-1 and the first-second pattern part P1-2.

The inflection point PI of the first-second pattern part P1-2 contacts the first-first virtual line VL1-1 and the first-second virtual line VL1-2. Accordingly, the first-second pattern P1-2 is not disposed between the first-first virtual line VL1-1 and the first-first pattern P1-1. Furthermore, the first-second pattern P1-2 is not disposed between the first-second virtual line VL1-2 and the first-first pattern P1-1.

The first-first pattern part P1-1 and the first-second pattern part P1-2 are spaced apart by a third distance D3.

The first distance D1 and the third distance D3 may be different. For example, the third distance D3 may be greater than the first distance D1.

For example, the third distance D3 may be 0.05 mm or greater. Specifically, the third distance D3 may be 0.05 mm to 0.8 mm, 0.055 mm to 0.75 mm, or 0.6 mm to 0.7 mm.

The second distance D2 may vary as it moves away from the folding axis of the elastic member in the second direction 2D.

For example, as illustrated in FIGS. 8 to 10, in a region close to the folding axis of the elastic member, the second distance D2 may be less than the first distance D1.

Alternatively, as shown in FIGS. 11 to 13, in a region far from the folding axis of the elastic member, the second distance D2 may be greater than the first distance D1 and less than twice the first distance D1.

Alternatively, as shown in FIGS. 14 and 15, in an intermediate region between a region close to the folding axis of the elastic member and a region far from the folding axis, the second distance D2 may be equal to the first distance D1.

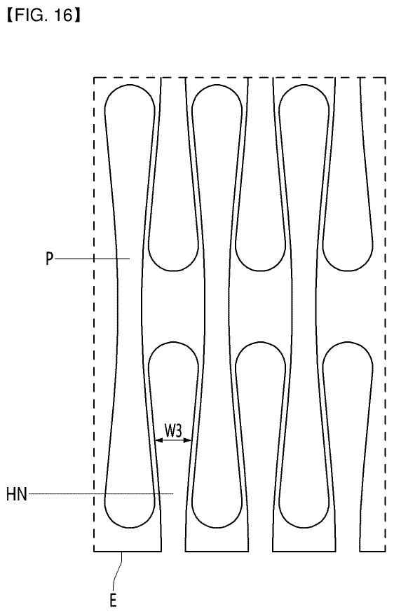

Referring to FIGS. 6 and 16, the first layer 100 includes a plurality of hinge parts HN. The hinge parts HN are formed by penetrating an end E of the first layer 100. A width W3 of the hinge parts HN varies. Specifically, the width W3 of the hinge parts HN increases as it moves away from the end E3. Accordingly, the width W3 of the hinge part HN is smallest in the region overlapping the end E3.

Therefore, when bonding the first layer 100 and the third layer 300, curling at the end of the first layer 100 can be prevented. Consequently, the reliability of the elastic member can be improved.

Furthermore, the strength of the end E of the first layer 100 can be prevented from decreasing. Consequently, damage to the end of the elastic member 100 can be prevented.

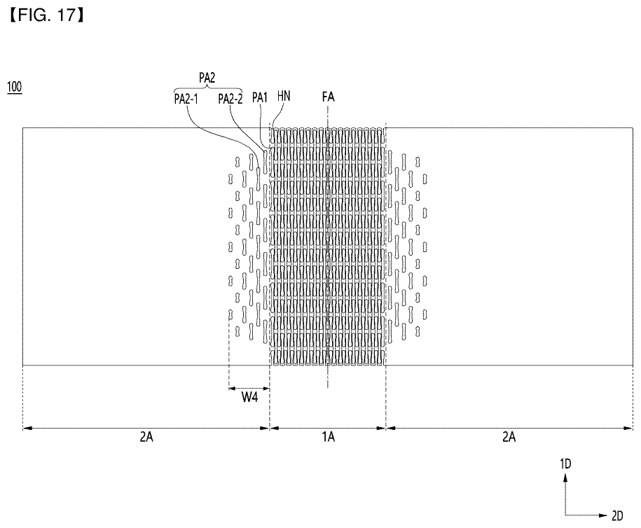

Referring to FIG. 17, the pattern part can also be disposed in the second region 2A. Specifically, the pattern part can include a first pattern part PA1 and a second pattern part PA2. The first pattern part PA1 is disposed in the first region 1A. The second pattern part PA2 is disposed in the first region or the second region.

A shape of a pattern of the first pattern part PA1 and a shape of a pattern of the second pattern part PA2 may be identical or similar.

A width W4 of a region where the second pattern part PA2 is formed may be smaller than a width of the first region 1A.

The second pattern part PA2 may include patterns having different sizes. Specifically, a size of the pattern of the second pattern part PA2 may decrease as it moves away from the first region 1A. That is, the second pattern part PA2 may include a gradient pattern.

For example, the second pattern part PA2 may include a second-first pattern part PA2-1 and a second-second pattern part PA2-2. A size of the pattern of the second-first pattern part PA2-1 may decrease as it moves away from the first region 1A. Accordingly, the pattern of the second-first pattern part PA2-1 is the largest in the pattern closest to the first region 1A, and the smallest in the pattern farthest from the first region 1A. A size of the pattern of the second-second pattern part PA2-2 may decrease as it moves away from the first region 1A. Therefore, the pattern of the second-second pattern part PA2-2 is the largest in the pattern closest to the first region 1A, and the smallest in the pattern farthest from the first region 1A.

The pattern of the second-first pattern part PA2-1 and the pattern of the second-second pattern part PA2-2 are disposed to partially overlap in the second direction 2D.

The occurrence of cracks at the boundary between the first region 1A and the second region 2A can be prevented by the second pattern part PA2. If a pattern part is formed only in the first region, a stress difference between the first region and the second region may increase. As a result, cracks may be formed at the boundary between the first region and the second region.

Therefore, the second pattern part is also disposed in the second region with a set width. Furthermore, the second pattern part is formed in a gradient pattern. Accordingly, the stress difference at the boundary between the first region and the second region may gradually decrease. Therefore, cracks may be prevented from forming at the boundary between the first region and the second region. As a result, reliability of the elastic member may be improved.

The second distance D2 in the first region may differ from the second distance D2 in the second region. Specifically, the second distance D2 in the first region may be smaller than the second distance D2 in the second region.

FIG. 18 is a diagram comparing the reaction force of the first layer 100 when the width of the pattern of the pattern part changes. FIG. 18 (a) is a diagram illustrating the reaction force of the first layer according to an embodiment. FIG. 18 (b) is a diagram illustrating the reaction force of the first layer according to a comparative example. In FIG. 18 (b), unlike the embodiment, the width of the pattern of the pattern part does not change. In addition, in FIG. 18 (b), unlike the embodiment, the width of the hinge part does not change.

Referring to FIG. 18, the maximum stress of the elastic member according to the embodiment is less than the maximum stress of the elastic member according to the comparative example. Also, referring to Table 1, the reaction force of the elastic member according to the embodiment is less than the reaction force of the elastic member according to the comparative example. Table 1 shows the measured repulsive force in an area of 80 mm*70 mm when a sample of 80*140 mm is folded at different curvatures.

The embodiment is a sample in which the inflection point PI of the first-second pattern part P1-2 is disposed in the region between the first-first virtual line VL1-1 and the first-first pattern P1-1, and the comparative example is a sample in which the second distance exceeds twice the first distance.

Furthermore, the overall stress distribution of the elastic member according to the embodiment is smaller than the overall stress distribution of the elastic member according to the comparative example. In particular, the stress in the residual region RA between adjacent pattern parts in the second direction is reduced. As the elastic member 1000 folds, torsion affects in the residual region RA due to stress. Accordingly, the residual region may be subjected to torsion. As a result, torsion in the residual region RA may vary depending on the position along the first direction. Therefore, stress in the residual region is reduced.

In the pattern part of the elastic member according to the comparative example, the residual region RA and the folding axis FA are parallel. That is, the entire residual region RA may be twisted uniformly. As a result, torsion is transmitted across the entire residual region (RA), causing large torsion to occur. As a result, the residual region of the pattern part of the elastic member in the comparative example may be significantly twisted.

On the other hand, in the pattern part of the elastic member according to the embodiment, the residual region RA and the folding axis FA are not parallel. That is, some residual regions are misaligned with the folding axis FA in one direction, and some residual regions are misaligned with the folding axis FA in another direction. Consequently, the torsion of the residual region RA can be offset. Consequently, the residual region of the pattern part of the elastic member according to the embodiment can be slightly twisted.

TABLE 1

| | Repulsion Force in | Repulsion force in |
|---|---|---|
| | Example (N) | Comparative Example (N) |
| 4.0 R | 0.05 | 0.11 |
| 3.5 R | 0.07 | 0.14 |
| 3.0 R | 0.09 | 0.20 |
| 2.5 R | 0.13 | 0.28 |

An elastic member according to a first embodiment includes a first layer, a second layer, and a third layer.

The first layer includes a first region and a second region. A pattern part is disposed in at least one of the first region and the second region.

The pattern part may include a first-first pattern and a first-second pattern adjacent to each other. Furthermore, a first-first virtual line, a first-second virtual line, and a second virtual line are defined by the pattern part.

The first-first virtual line passes through the inflection point of the first-first pattern. Furthermore, the first-second virtual line passes through the inflection point of the first-second pattern. Furthermore, the second virtual line passes through the center of the pattern.

The inflection point of the second pattern part may be disposed in a region between the first-first virtual line and the first-first pattern part. Alternatively, the inflection point of the second pattern part may not be disposed in the region between the first-first virtual line and the first-first pattern part. Alternatively, the inflection point of the second pattern part may contact the first-first virtual line. That is, the first-first virtual line and the first-second virtual line may overlap. This may vary depending on the position of the elastic member in the second direction.

Therefore, when folding the elastic member, the stress applied to the first layer is reduced. Furthermore, when folding the elastic member, the repulsive force of the first layer is reduced. Furthermore, when folding the elastic member, the torsion of the residual region between adjacent patterns is reduced.

Therefore, the elastic member according to the embodiment has improved folding characteristics and reliability.

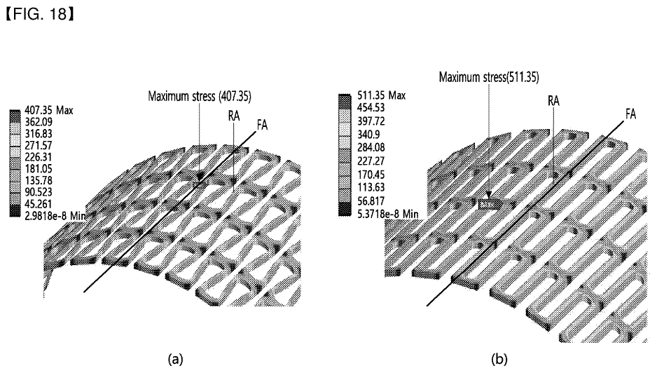

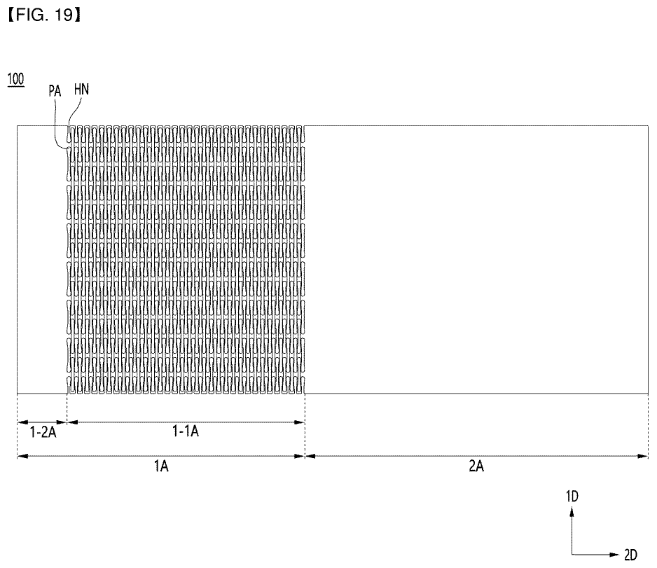

Hereinafter, an elastic member according to the second embodiment will be described with reference to FIGS. 19 to 21. Descriptions identical to those of the first embodiment will be omitted. The same reference numerals are assigned to the same configuration as the first embodiment.

Referring to FIGS. 19 to 21, the first layer 100 is bendable. Furthermore, the first layer 100 can slide. Specifically, the first region 1A includes a sliding region.

The first region 1A includes a plurality of regions. The first region 1A includes a first-first region 1-1A and a first-second region 1-2A. The first-second region 1-2A is disposed at one side of the first-first region 1-1A. The first-second region 1-2A is disposed further outward of the elastic member in the second direction than the first-first region 1-1A.

The first-first region 1-1A can bend. Therefore, the first-first region 1-1A is defined as a sliding region. The first-second region 1-2A does not bend. Therefore, the first-second region 1-2A is defined as an un-sliding region. The first-second region 1-2A may be a region connected to another member. Additionally, the second region 2A does not bend.

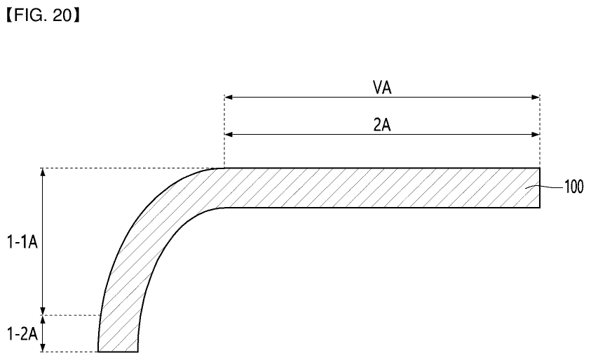

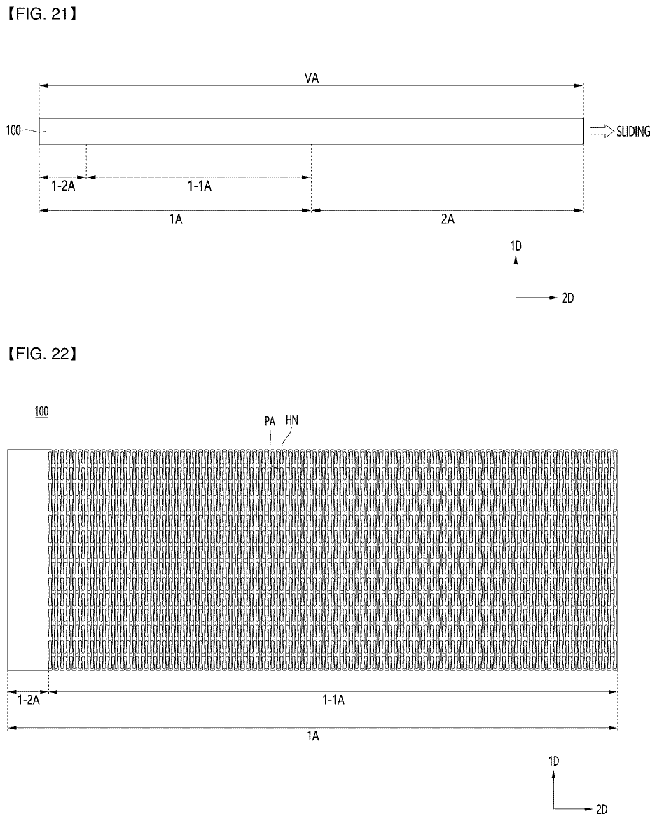

Referring to FIGS. 20 and 21, a size of a screen region VA of the first layer 100 may vary depending on the first-first region 1-1A.

Referring to FIG. 20, the first-first region 1-1A slides in a first sliding mode. The first-first region 1-1A does not display a screen in the first sliding mode.

Referring to FIG. 21, the first-first region 1-1A slides in a second sliding mode. The first-first region 1-1A displays a screen in the second sliding mode.

Accordingly, the first-first region 1-1A selectively displays a screen.

If the user wants to use a narrow screen region, the screen is displayed in the first sliding mode. Furthermore, if the user warts to use a wider screen region, the screen is displayed in the second sliding mode. Accordingly, the user can use various screen regions depending on the desired mode.

The first region 1A is provided with the same pattern parts as the first embodiment. Accordingly, the folding characteristics and reliability of the elastic member can be improved.

Hereinafter, an elastic member according to a third embodiment will be described with reference to FIGS. 22 to 24. Descriptions identical to those of the first embodiment will be omitted. Components identical to those of the first embodiment are designated by the same reference numerals.

Referring to FIGS. 22 to 24, the first region 1A includes a plurality of regions. The first region 1A includes a first-first region 1-1A and a first-second region 1-2A. The first-second region 1-2A is disposed at one side of the first-first region 1-1A. The first-second region 1-2A is disposed further outward of the elastic member in the second direction than the first-first region 1-1A.

The first-first region 1-1A is bendable. Furthermore, the first-first region 1-1A may be bent. The first-first region 1-1A is defined as a rolling region. The first-second region 1-2A does not bend. The first-second region 1-2A may be a region connected to another member.

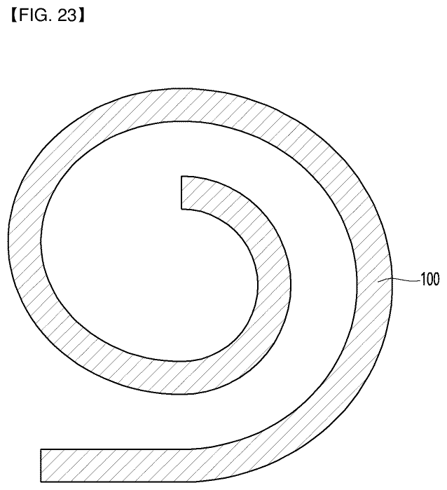

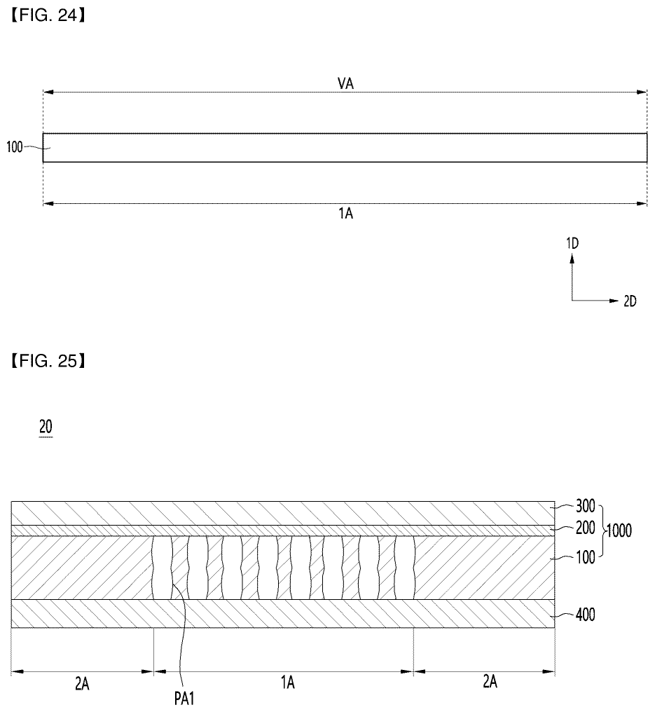

Referring to FIGS. 23 and 24, the size of the screen region VA of the first layer 100 may vary depending on the first-first region 1-1A.

Referring to FIG. 23, the first-first region 1-1A rolls in a first rolling mode. The first-first region 1-1A does not display a screen in the first rolling mode.

Referring to FIG. 24, the first-first region 1-1A rolls in a second rolling mode. The first-first region 1-1A displays a screen in the second rolling mode.

Therefore, the first region 1A selectively displays a screen.

If the user does not wish to use the screen region, it rolls in the first rolling mode. This allows the user to easily carry or store the display device. Furthermore, if the user wishes to use the screen region, it rolls in the second rolling mode. This allows the user to use the screen region via the display device.

The first-first region 1-1A is provided with the same pattern part as in the first embodiment. This improves the folding characteristics and reliability of the elastic member.

Hereinafter, with reference to FIG. 25, a folding support 20 including an elastic member according to an embodiment will be described.

Referring to FIG. 25, the folding support 20 includes an elastic member 1000 and a protective layer 400.

The protective layer 400 is disposed under the elastic member 400. For example, an adhesive layer is disposed between the protective layer 400 and the elastic member 1000. The elastic member 1000 and the protective layer 400 can be bonded by the adhesive layer.

The protective layer 400 may have a color. For example, the protective layer 400 may have a black color.

The protective layer 400 may include metal particles. For example, the protective layer 400 may include copper particles. Accordingly, the thermal conductivity of the protective layer 400 may be improved. Accordingly, heat generated in the display device can be dissipated by the protective layer 400.

A thickness of the protective layer 400 may be smaller than a total thickness of the elastic member 1000. That is, the thickness of the protective layer 400 may be smaller than the sum of the thicknesses of the first, second, and third layers of the elastic member 400.

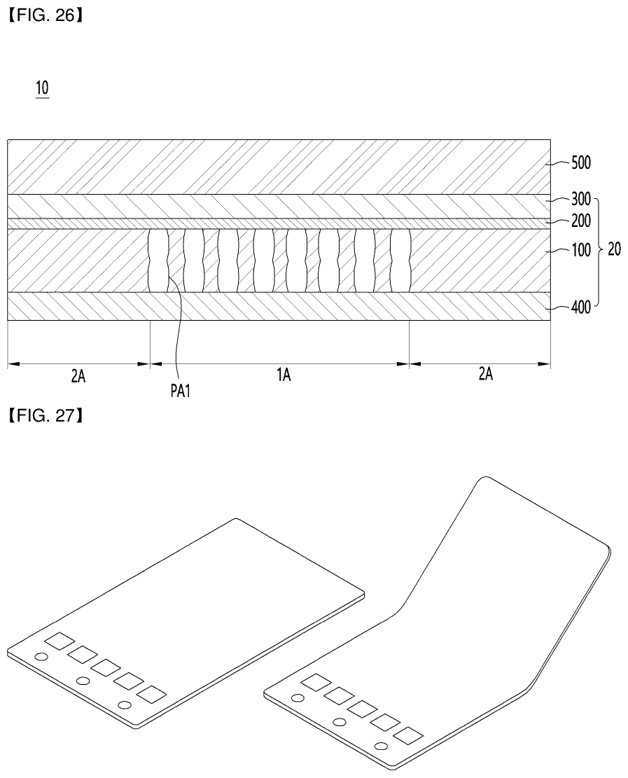

Hereinafter, a display device including a flexible support according to an embodiment will be described with reference to FIG. 26.

Referring to FIG. 26, the display device 10 may include the flexible support 20 and a panel layer 500.

The panel layer 500 may include at least one panel of the display panel and the touch panel.

An adhesive layer may be disposed between the flexible support 20 and the panel layer 500. The flexible support 20 and the panel layer 500 can be bonded by the adhesive layer.

The elastic member 1000 may flatten an adhesive surface of the elastic member by a third layer 300. Therefore, the elastic member and the panel layer may be easily adhered to each other.

FIG. 27 is a drawing illustrating an example of an application of an elastic member according to embodiments.

Referring to FIG. 27, the elastic member according to embodiments can be applied to a flexible or foldable display device that displays a screen.

For example, the elastic member according to embodiments can be applied to a flexible display device including a mobile phone or tablet. As a result, the display device can be bended or folded.

The display device can be easily folded by the elastic member. Furthermore, the folding reliability of the display device can be improved.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. An elastic member comprising:
a first layer foldable based on a folding axis and having a first direction corresponding to the folding axis and a second direction perpendicular to the first direction;
wherein the first layer includes a pattern part disposed in a first region adjacent to the folding axis, the pattern part including a first-first pattern and a first-second pattern that are disposed adjacent to each other in the second direction,
wherein the first-first pattern includes a plurality of first inflection points in which a direction of curvature changes as a distance from a first center of the first-first pattern increases,
wherein the first-second pattern includes a plurality of second inflection points in which a direction of curvature changes as a distance from a second center of the first-second pattern increases,
wherein the first-first pattern and the first-second pattern include a plurality of virtual lines defined on based on the plurality of first inflection points, the plurality of second inflection points, the first center, and the second center,
wherein the plurality of virtual lines include a first-first virtual line passing through two first inflection points that are spaced apart from each other in the first direction of the first-first pattern, a first-second virtual line passing through two second inflection points that are spaced apart in the first direction of the first-second pattern and are adjacent to the first-first pattern, and a second virtual line extending in the second direction and passing through the first center,
wherein, on the second virtual line, the first-first virtual line and the first-first pattern are spaced apart by a first distance along the second direction,
wherein, on the second virtual line, the first-second virtual line and the first-first pattern are spaced apart by a second distance along the second direction, and
wherein the second distance is less than or equal to twice the first distance.

2. The elastic member of claim 1, wherein the two second inflection points of the first-second pattern are disposed in a region between the first-first virtual line and the first-first pattern.

3. The elastic member of claim 1, wherein the two second inflection points of the first-second pattern are disposed between the first-first virtual line and the first center of the first-first pattern in the second direction.

4. The elastic member of claim 1, wherein a partial region of the first-second pattern is disposed in a region between the first-first virtual line and the first-first pattern.

5. The elastic member of claim 4, wherein the partial region of the first-second pattern overlaps the first-first pattern along the first direction.

6. The elastic member of claim 1, wherein the first distance is greater than the second distance.

7. The elastic member of claim 1, wherein the first distance is smaller than the second distance.

8. The elastic member of claim 1, wherein the first-first pattern and the first-second pattern are spaced apart by a third distance along the second direction, and
wherein the third distance is greater than the first distance.

9. The elastic member of claim 1, wherein at least one of the two inflection points of the first-second pattern is in contact with the first-first virtual line.

10. The elastic member of claim 1, wherein the first layer includes a plurality of hinge parts penetrating an end in the first direction.

11. The elastic member of claim 10, wherein the plurality of hinge parts include a region whose width in the second direction changes along the first direction.

12. The elastic member of claim 11, wherein the width of the hinge part in the second direction increases as a distance from the end increases.

13. The elastic member of claim 11, wherein the width of the hinge part in the second direction is smallest at the end.

14. The elastic member of claim 1, wherein the first-first pattern has a first width corresponding to a distance between two first inflection points facing in the second direction, and a second width smaller than the first width on the second virtual line.

15. The elastic member of claim 1, wherein the first-second pattern has a third width corresponding to a distance between two second inflection points facing in the second direction, and a fourth width smaller than the third width on a third virtual line passing through the second center in the second direction.

16. The elastic member of claim 1, wherein each of the first-first pattern and the first-second pattern includes a plurality of patterns spaced apart in the first direction, and
wherein a first spacing in the first direction between a plurality of adjacent first-first patterns is greater than a second spacing in the first direction between a plurality of adjacent first-second patterns.

17. The elastic member of claim 1, wherein the first region includes a first-first region and a first-second region that that is located farther from the folding axis than the first-first region, and
wherein the pattern part is formed in the first-first region.

18. The elastic member of claim 1, further comprising:
a second layer disposed on the first layer; and
a third layer disposed on the second layer,
wherein the first layer includes metal,
wherein the third layer includes plastic, and
wherein the second layer is an adhesive layer disposed between the first layer and the third layer.
